(19) United States
(12) Patent Application Publication
(10) Pub. No.: US 2025/0141154 A1
(43) Pub. Date: May 1, 2025

(54) MODULAR POWER METER ASSEMBLY

(71) Applicant: Accuenergy (Canada) Inc., Toronto (CA)

(72) Inventors: Yufan Wang, Toronto (CA); Ketao Li, Toronto (CA); Liang Wang, Toronto (CA)

(73) Assignee: Accuenergy (Canada) Inc., Toronto (CA)

(21) Appl. No.: 18/498,066

(22) Filed: Oct. 31, 2023

(51) Int. Cl. H01R 13/639; G01R 1/04; G01R 21/00; H01R 43/26

(52) U.S. Cl. CPC H01R 13/639; G01R 1/04; G01R 21/00; H01R 43/26; H01R 2201/20

(57) ABSTRACT

The invention presents a power meter assembly devised for comprehensive measurement of electrical parameters within power distribution systems. This assembly integrates a primary power meter, housed within a first housing, with an extension module encased in a secondary housing to expand its functionality. The design prioritizes precision, incorporating features like strategically positioned engagement apertures, access holes, and cylindrical protrusions for exact alignment during module assembly. Central to the assembly's innovative mechanism is a dynamic locking system situated on the lateral aspect of the extension module. This system combines transverse and longitudinal displacement elements, both furnished with actuators, and a mechanical locking element. The unique interplay between these components allows for swift pre-engagement configurations, culminating in a robust and secure locked state after actuation. This ensures a stable connection between the primary power meter and its extension module, facilitated by the meticulous interlocking of the cylindrical protrusion within the access hole.

### FIELD OF THE INVENTION

The present disclosure generally relates to the field of power metering devices used in power distribution systems and, more specifically, to a power meter assembly and a power meter extension module.

### BACKGROUND OF THE INVENTION

Power meters have become indispensable tools in modern power distribution systems. They measure and monitor electrical parameters, providing vital data for managing energy consumption, detecting anomalies, and ensuring overall system efficiency. With the increasing complexity of power distribution networks, there is a growing need to enhance the functionality of power meters. This has led to the development of power meter extension modules that can be integrated into the primary meter to provide additional capabilities.

Historically, integrating extension modules into power meters posed challenges. The attachment mechanisms were often cumbersome, prone to misalignment, and did not always ensure a stable and secure connection. It was crucial to have a robust connection between the primary meter and the extension module to ensure accurate data collection and prevent disruptions.

Furthermore, previous designs required manual intervention and multiple steps to secure the extension module to the power meter. This process was time-consuming and often led to errors due to misalignment, poor fit, or incorrect insertion of components. Thus, there has been a need for an improved power meter assembly that facilitates easy and precise integration of extension modules.

### SUMMARY OF THE INVENTION

The present invention pertains to a power meter assembly devised to enhance measurement capabilities and provide flexibility in terms of system expansion. The core of this assembly consists of a power meter housed in a primary container, well-suited for capturing various electrical parameters across any metered point in an electrical power distribution setup. Notably, this primary meter encompasses engagement apertures and access holes, both astutely placed on its lateral face to welcome associated assembly components.

For amplifying the inherent capabilities of the primary power meter, an extension module is introduced. This module, safeguarded within its distinct housing, brings forth cylindrical protrusions, mechanically inclined locking elements, and a dynamic locking apparatus. Together, these constituents ascertain exact alignment during the amalgamation phase. The dynamic locking mechanism, in particular, stands out due to its incorporation of both transverse and longitudinal displacement elements, each boasting its actuator. The synchronized operation of these elements paves the way for transitioning the mechanical lock into a preliminary engagement setting, eventually culminating in a fortified lock state.

Furthermore, the invention ensures electrical connectivity between the primary power meter and its extension via male and female connectors. These connectors, strategically positioned on the respective modules, interact seamlessly, achieving a robust electrical link when the modules are merged. The innovative locking mechanism also houses certain engagement components and spring elements which play pivotal roles during the actuation process. Their collective functioning guarantees that the mechanical lock remains steadfastly in its desired configuration.

The assembly also features an upward movement of the longitudinal displacement element, leading to the interplay between various engagement components and ultimately, the attainment of a steadfast locked state. The association of specific components, such as the slope-shaped engagement constituent, with the longitudinal displacement element, is also noteworthy.

Additionally, the extension module in isolation is characterized by various engagement apertures, access holes, cylindrical protrusions, and a locking mechanism-all designed with precision to ensure accurate and stable assembly with either another power meter or a further extension module.

The inventive scope extends to a novel method of interfacing a pair of power meter extension modules. This procedure champions an angled rotational technique, commencing with actuator initiation and culminating in the establishment of a sturdy connection. The entire operation emphasizes acute inclinations, rotational movements, and the meticulous engagement of mechanical locks, ensuring the modules come together in a co-planar fashion.

### BRIEF DESCRIPTION OF THE DRAWINGS

The forgoing and other advantages of the present disclosure will become apparent upon reading the following detailed description and upon reference to the drawing.

FIG. 1 is a functional block diagram of an exemplary power meter connected with optional power meter extension modules.

FIG. 2 is a front, top, left perspective view of power meter extension modules mounted on a DIN rail.

FIG. 3 is a front, top, right perspective view of power meter extension modules mounted on a DIN rail.

FIG. 4 is a left perspective view of a power meter extension, illustrating the condition wherein the attachment actuator is in an actuated state and mechanical locking elements are set in a pre-engagement configuration.

FIG. 5 is a left perspective view of a power meter extension, illustrating the condition wherein the lock engagement actuator is in an actuated state and mechanical locking elements are set in a locked state.

FIG. 6 is a front, top, right perspective view of power meter extension modules securely affixed to a DIN rail, illustrating the condition wherein the attachment actuator is in an actuated state and mechanical locking elements are set in a pre-engagement configuration.

FIG. 7 is a front, top, right perspective view of power meter extension modules securely affixed to a DIN rail, illustrating the condition wherein the lock engagement actuator is in an actuated state and mechanical locking elements are set in a locked state.

FIG. 8 is a front, top perspective view of power meter extension modules, with one such module securely mounted on a DIN rail, illustrating the angled rotational attachment method.

FIG. 9 is an exploded perspective view of the constituent components of power meter extension modules.

FIG. 10 is a left perspective view of the body component of a power meter extension module.

FIG. 11 is a left perspective view of the body constituent of a power meter extension module, specifically depicting the inclusion of the longitudinal displacement element as integrated within the assembly.

FIG. 12 is a left perspective view of the body constituent of a power meter extension module, featuring the installation of the transverse displacement element as an integral component of the assembly.

FIG. 13 is a left perspective view of the body constituent of a power meter extension module, showcasing the transverse and longitudinal displacement elements as core components, with the mechanical locking elements in a pre-engagement configuration.

FIG. 14 is a left perspective view of the body constituent of a power meter extension module, highlighting the transverse and longitudinal displacement elements as primary components, with the mechanical locking elements positioned in a locked state.

FIG. 15 is a front, top, right perspective view of a power meter assembly including a power meter and two power meter extension modules affixed on a DIN rail.

### DETAIL DESCRIPTIONS OF THE INVENTION

The following description should be read with reference to the drawings, in which like elements in different drawings are numbered in like fashion. The drawings, which are not necessarily to scale, depict selected embodiments and are not intended to limit the scope of the invention. Although examples of construction, dimension, and materials are illustrated for the various elements, those skilled in the art will recognize that many of the examples provided have suitable alternatives that may be utilized.

Herein the terms “up,” “down,” “right,” and “left” are relative terms used to describe the orientation or direction of components, primarily for the ease of understanding the invention. They serve as spatial references to facilitate the description and are generally defined in relation to the figures presented in the drawings. It's essential to note that these terms are not intended to limit the invention to any specific orientation or spatial configuration unless explicitly stated.

In most cases, the use of these terms is standardized to match the orientation as presented in the drawings accompanying the patent application. However, the terms are relative to the “viewer” or the point of view in the drawings, and not necessarily indicative of a fixed spatial orientation in real-world use of the invention.

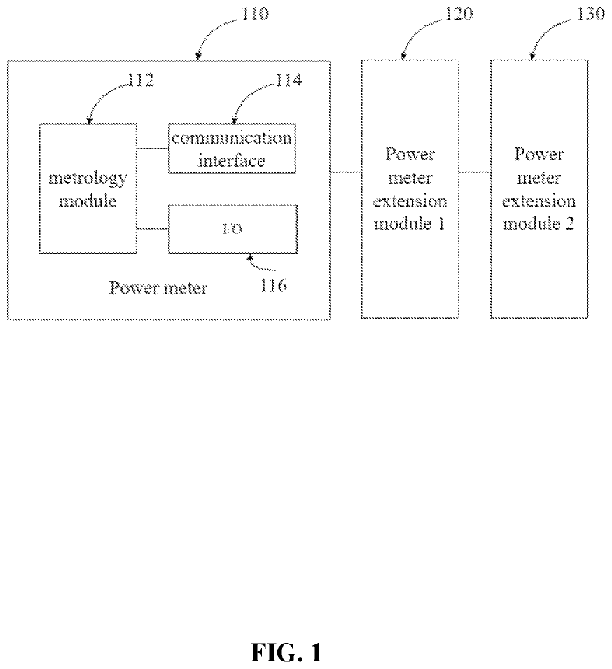

In FIG. 1, the power meter 110 is depicted as a robust unit capable of interfacing with one or more power meter extension modules (120, 130). The metrology module 112 in power meter 110 is engineered for precise measurement of electrical parameters at any metered location within a power distribution system. The communication module 114 facilitates data transmission between interconnected devices, while I/O 116 serves as the primary interface for both input and output operations. Power meter extension module 120, augmenting the base functionalities, incorporates extra input/output channels to handle increased data. Similarly, power meter extension module 130 enriches the system with advanced communication functionalities, ensuring seamless data interchange within the extended power metering network.

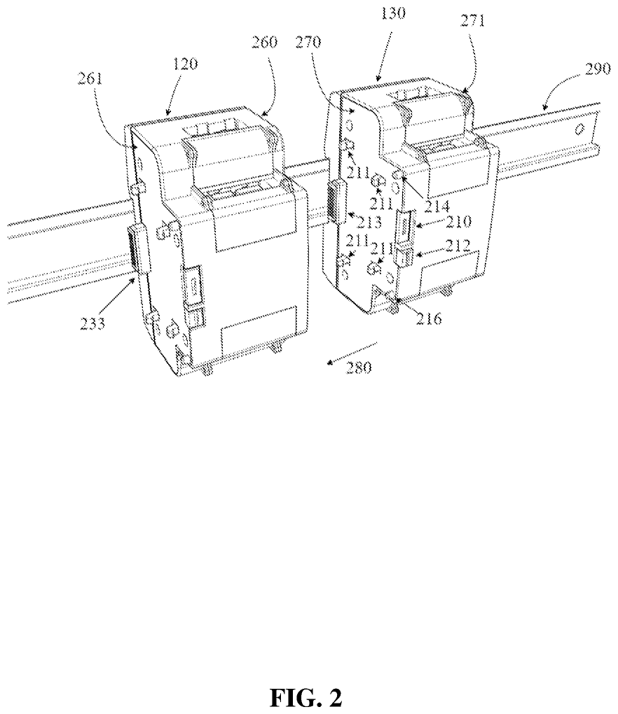

FIG. 2 illustrates a pair of power meter extension modules, specifically modules 120 and 130, that are securely affixed to a DIN rail, denoted by reference numeral 290. Externally, modules 120 and 130 are designed with identical structural configurations to ensure uniformity and ease of installation. The left lateral aspect of module 120, labeled with reference numeral 261, is indistinguishable in form from the corresponding left lateral aspect of module 130, identified by reference numeral 270. In a similar manner, the right lateral aspect of module 120, designated by reference numeral 260, is structurally identical to its counterpart on module 130, which is marked by reference numeral 271. Both modules also incorporate the same dynamic locking mechanism 980 to streamline the attachment and detachment procedures.

In the detailed description herein, the left lateral aspect 270 of module 130 is comprehensively elaborated. It should be understood by those of ordinary skill in the art that the characterizations and specifications associated with left lateral aspect 270 of module 130 are equally applicable to the left lateral aspect 261 of module 120. Similarly, the right lateral aspect 260 of module 120 has been meticulously detailed. Those with ordinary skill in the pertinent art should recognize that the elucidations pertaining to the right lateral aspect 260 of module 120 are correspondingly relevant to the right lateral aspect 271 of module 130.

Despite these structural similarities, modules 120 and 130 serve distinct functions within the power meter system. Module 120 operates as an Input/Output (IO) extension, while module 130 functions as a dedicated communication extension module. This functional divergence allows for greater flexibility and customization in system configurations without the need for different mounting or installation procedures, owing to their identical external design and locking mechanisms.

To commence the installation procedure, user actuation of the attachment actuator, designated as element 210, is requisite. Upon such actuation, the mechanical locking elements, identified by reference numeral 211, transition into a pre-engagement configuration. It is noteworthy that this pre-engagement configuration remains stable even in the absence of continued manual pressure on the attachment actuator 210. The term “pre-engagement configuration” refers to the state wherein the mechanical locking elements 211 are positioned for insertion into the engagement aperture 311.

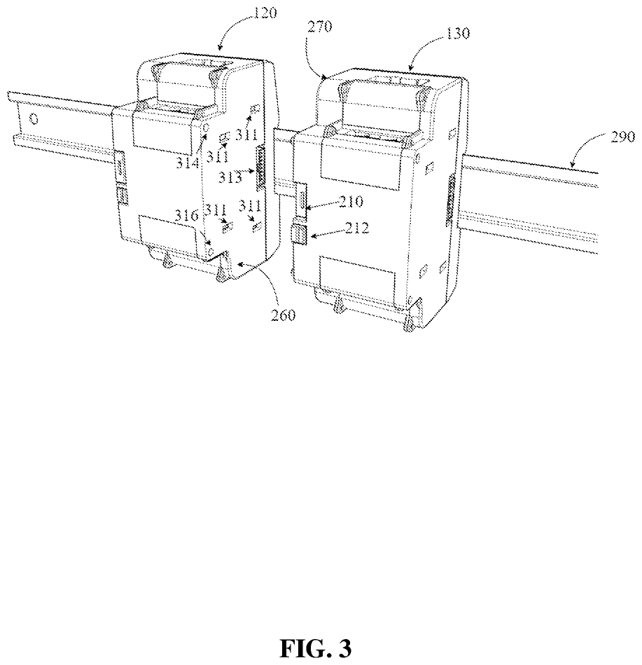

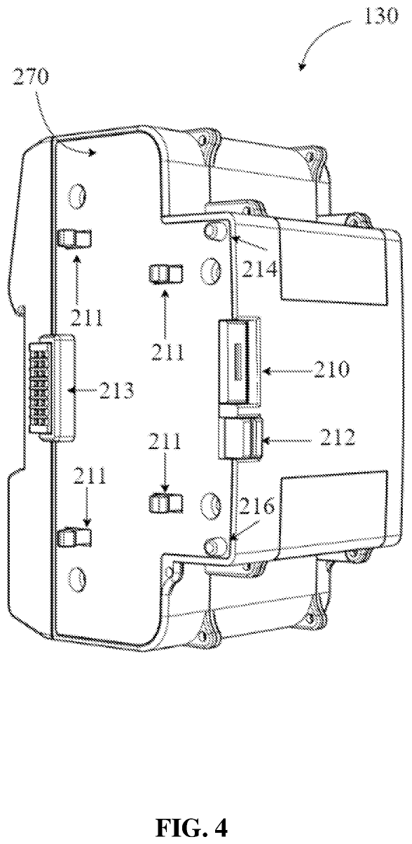

As delineated in greater detail in FIGS. 2 and 4, user actuation of the attachment actuator, designated as element 210, occurs in tandem with the depression of the mechanical locking elements, identified by reference numeral 211. The architecture of the system is configured such that these mechanical locking elements 211 achieve alignment with, and are capable of insertion into, complementary apertures, designated by reference numeral 311, situated on the right lateral aspect 260 of module 120. In the course of translational movement of module 130 along the DIN rail 290, oriented as indicated by arrow 280, the aforementioned mechanical locking elements 211 are duly inserted into the respective apertures 311. Concomitantly, cylindrical protrusions, identified as elements 214 and 216, achieve alignment with and are inserted into designated access holes 314 and 316, as illustrated in FIG. 3. A male connector, designated as element 213, engages a corresponding female connector, identified by reference numeral 313, effectuating an electrical interconnection between modules 120 and 130. This attachment procedure may be denominated as the slide-and-lock method, characterized by securing the module along the DIN rail track, denoted by reference numeral 290.

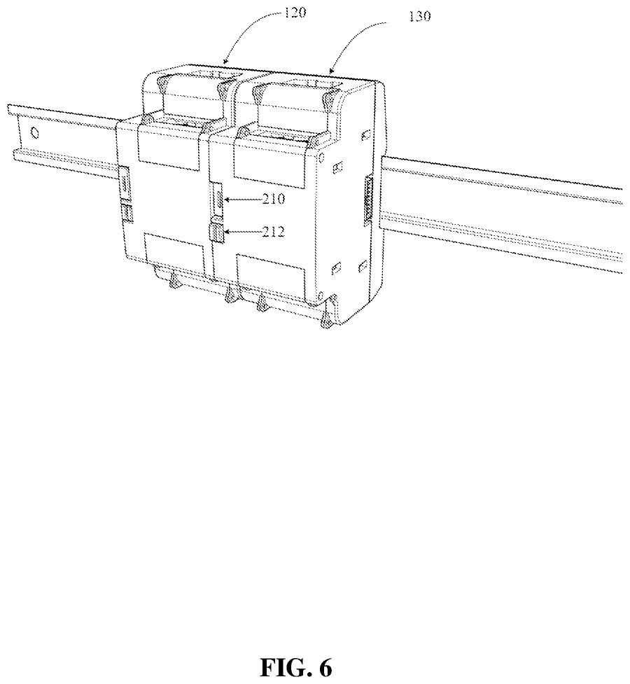

Once modules 120 and 130 are successfully attached, as shown in FIG. 6, the user may then actuate the lock engagement actuator 212. This results in the mechanical locking elements 211 becoming securely engaged with module 120. Engagement is achieved through the hooked feature located atop the mechanical locking elements 211.

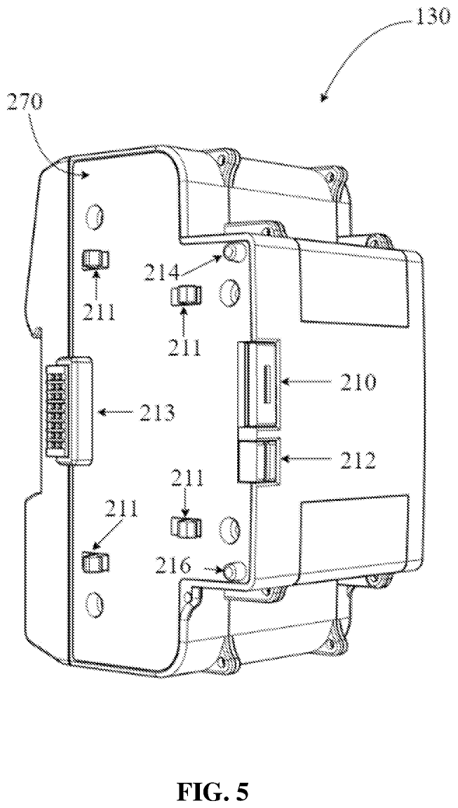

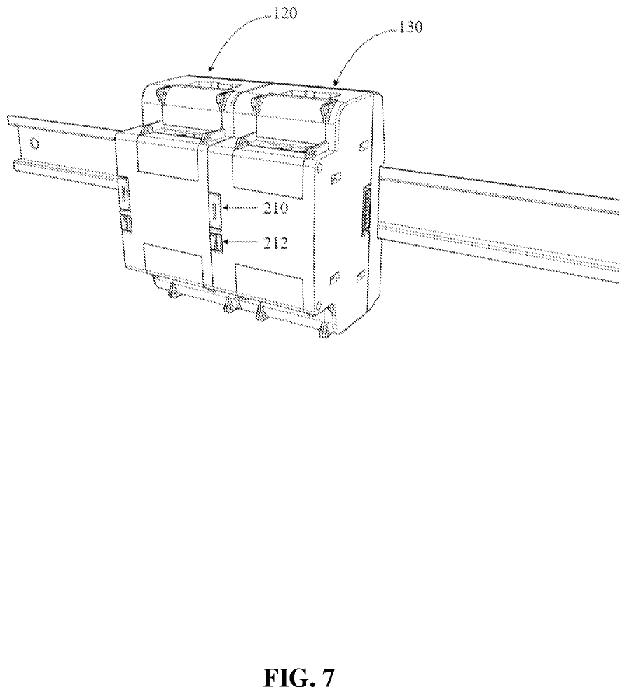

Following the scenarios outlined in FIG. 5 and FIG. 7, activation of the lock engagement actuator, denoted by reference numeral 212, prompts the attachment actuator 210 to return to its initial state, colloquially described as ‘bouncing back.’ Concurrent with this reversion, the mechanical locking elements 211—interlinked with the attachment actuator 210—undergo retraction and engage with the inner contour surrounding the engagement apertures 311 located on the right lateral aspect of module 120, designated by reference numeral 260.

Upon actuation, the mechanical locking elements denoted by reference numeral 211 enter a locked state. Importantly, this locked state is maintained even without sustained manual force applied to the lock engagement actuator 212. The “locked state” describes the condition where the mechanical locking elements 211 engage securely with the inner contour of the engagement apertures 311 on the right lateral aspect of module 120, ensuring a robust attachment of module 130 to module 120.

To streamline the process of detaching module 130 from module 120, the present invention incorporates a specialized disengagement mechanism into the dynamic locking mechanism situated on the left lateral aspect of module 130, labeled by reference numeral 270. This disengagement mechanism collaborates synergistically with the attachment actuator, identified as element 210, and the mechanical locking elements, designated as 211, to facilitate an intuitive and efficient detachment procedure.

To commence the detachment procedure, a user is required to activate the attachment actuator 210 as shown in FIG. 6. On activation, an embedded spring mechanism within the dynamic locking mechanism 980 is actuated. This action induces the mechanical locking elements 211 to disengage from the inner contour surrounding the engagement apertures 311, which are situated on the right lateral aspect of module 120, as indicated by reference numeral 280.

Once the attachment actuator 210 is actuated and the mechanical locking elements 211 are disengaged, the user is then able to slide module 130 along the DIN rail 290, in the direction opposite to that indicated by arrow 280. This movement enables the complete separation of module 130 from module 120. Concurrently, the male connector 213 disengages from the female connector 313, thereby interrupting the electrical connection between modules 130 and 120. Additionally, cylindrical protrusions 214 and 216 retract from access holes 314 and 316, respectively.

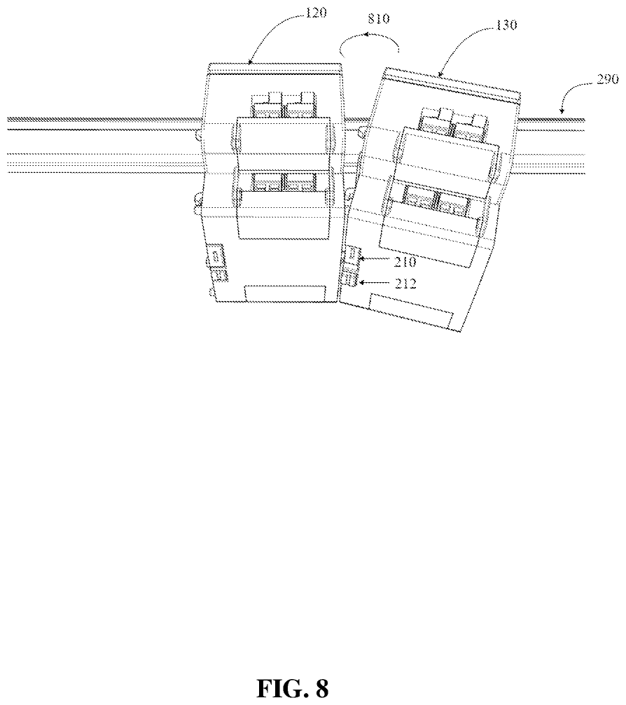

FIG. 8 presents an alternative methodology for attaching module 130 to module 120. In this configuration, module 120 is securely mounted on the DIN rail, denoted by reference numeral 290, whereas module 130 remains unattached to the DIN rail. This attachment procedure may be denominated as the angled rotational attachment method, characterized by the initial positioning of module 130 at a sharp angle relative to module 120, followed by a rotational motion to secure the modules together.

To commence the installation, the user must first depress the attachment actuator 210 located on module 130. While holding module 130, it is positioned such that it forms a sharp angle relative to module 120. The user then carefully moves module 130 closer to module 120, ensuring that cylindrical protrusions 214 and 216 align with and are inserted into access holes 314 and 316, respectively.

Subsequent to this alignment, the user rotates module 130 in the direction illustrated by arc 810. This rotational motion continues until modules 130 and 120 become securely attached to each other. After the successful attachment, which is also depicted in FIG. 6 for reference, the user actuates the lock engagement actuator 212. Actuation of the lock engagement actuator results in the mechanical locking elements 211 engaging securely with module 120, thus completing the installation.

The described alternative method of attachment is particularly advantageous in scenarios where installation space is constrained, offering flexibility in the setup process.

After the successful attachment of modules 130 and 120 via the alternative method illustrated in FIG. 8, the detachment procedure remains identical to the one previously outlined. Specifically, the user would actuate the attachment actuator 210 to disengage the mechanical locking elements 211 and proceed with the detachment as described earlier in the specification.

In the angled rotational attachment method illustrated in FIG. 8, the cylindrical protrusions 214 and 216 play a critical role in initial alignment during the attachment process. When the user holds module 130 at a sharp angle relative to module 120, the cylindrical protrusions 214 and 216 align with specific access holes 314 and 316 on module 120. This alignment serves as a preliminary positioning guide and provides added mechanical stability during the subsequent rotational motion. The rotation action that follows helps bring the two modules closer in a controlled manner and contributes to a secure attachment. In essence, the cylindrical protrusions 214 and 216 in this method function as both alignment guides and stabilizing elements during rotation.

In contrast, in the slide-and-lock method illustrated in FIG. 3, the cylindrical protrusions serve primarily as a guide during the sliding motion of module 130 along the DIN rail to join it with module 120. Their entry into the access holes ensures that the mechanical locking elements 211 will subsequently align with their respective apertures. Once the sliding is complete, the protrusions contribute to holding the modules in place but do not play as significant a role in the actual attachment process as they do in the angled rotational attachment method. Here, they function more as alignment aids and secondary locking elements.

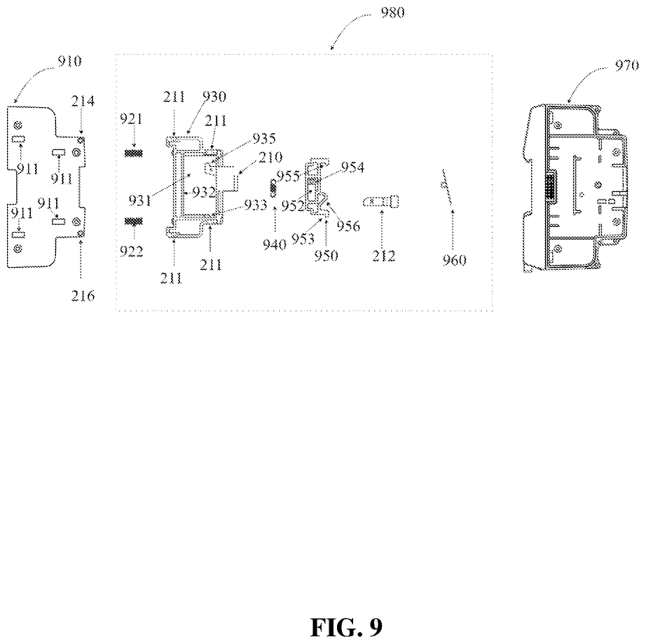

FIG. 9 presents an exploded view detailing the components of module 130. Externally, the module is encased by a shell, designated by reference numeral 910. Positioned internally to the shell, yet external to the body of the module, is the dynamic locking mechanism 980. This mechanism is comprised of several components: springs 921 and 922, a double-hook spring 940, a transverse displacement element 930, a longitudinal displacement element 950, a lock engagement actuator 212, and a torsion spring 960. At the innermost part of the module is the body, denoted by reference numeral 970.

Within the shell, designated by reference numeral 910, four engagement apertures are tactically situated and annotated as 911. These engagement apertures permit the mechanical locking elements, identified by reference numeral 211, to protrude beyond the shell's exterior surface. Additionally, a cylindrical protrusion, labeled as 214, is positioned at the upper right corner of the shell 910. A second cylindrical protrusion, designated by reference numeral 216, is situated at the lower right corner of the shell 910.

The transverse displacement element 930, incorporates an attachment actuator 210, and is equipped with four mechanical locking elements, each identified by reference numeral 211. Situated in the central region of this transverse displacement element 930 is a rectangular hollow section, annotated as 931. At the leftmost extremity of the hollow section 931, there exists an engagement projection, designated by reference numeral 932. This engagement projection serves a specific functional purpose within the mechanics of the locking mechanism 980. In a similar vein, positioned at the upper right corner of the hollow section 931 is an engagement component, annotated as 935. Additionally, another engagement component, labeled as 933, is located at the lower right corner of the same hollow section 931.

These components, namely the engagement projection 932 and the engagement components 933 and 935, are designed to interact with the corresponding elements within the locking mechanism to facilitate the secure attachment and detachment of module 130 to and from module 120.

This transverse displacement element 930 is actuated through the action of springs 921 and 922, facilitating its lateral movement.

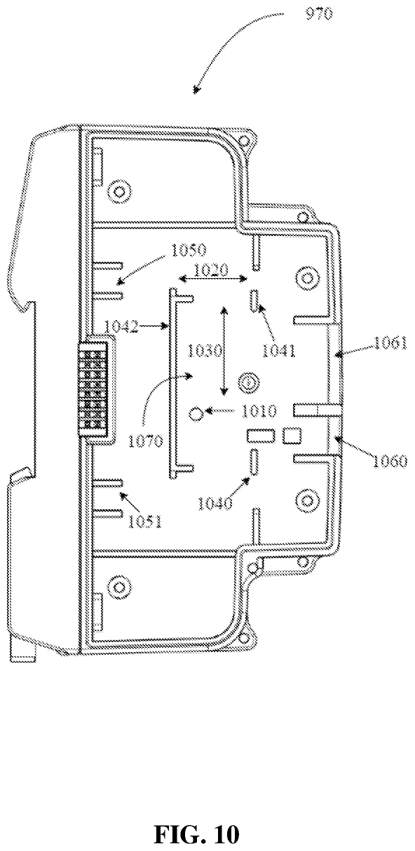

The longitudinal displacement element 950, is expressly designed to undergo longitudinal movement under the actuating force of a double-hook spring 940. This moving part contains a rectangular hollow section situated centrally, labeled as 952. Positioned at the top of this hollow section 952 is a protruding object, designated as 954. One hook of the aforementioned double-hook spring 940 secures itself to this protruding object 954, while the opposing hook affixes to a secondary protruding object, identified as 1010 in FIG. 10, located on the body denoted as 970.

Additionally, situated at the upper right quadrant of the longitudinal displacement element 950 is an engagement component annotated as 955. Another engagement component, labeled as 953, is located at the lower right quadrant of the moving part. The engagement component 955 is engineered to engage with the previously described engagement component 935. This interaction serves to facilitate the secure attachment and detachment of module 130 with respect to module 120. In a similar manner, the engagement component 953 is tailored to engage with engagement component 933, further aiding in the secure assembly and disassembly process involving modules 130 and 120.

Finally, a slope-shaped engagement component, identified as 956, is incorporated into the design. The longitudinal movement of the longitudinal displacement element 950 is actuated when lock engagement actuator, designated as 212, exerts force upon this slope-shaped engagement component 956.

Additionally, the torsion spring 960 is designed to connect with both the attachment actuator 210 and the lock engagement actuator 212. This connection ensures that only one of these actuators remains in an actuated state at any given moment, thereby preventing conflicting actions.

FIG. 10 delivers an enlarged, detailed view that clarifies the features of body 970 within module 130. Situated at the upper left of the body 970 is a spring chamber, designated by reference numeral 1050, engineered to house spring 921. A corresponding spring chamber, denoted as 1051, exists at the lower left of the body to accommodate spring 922. Adjacent to the right side of these spring chambers, 1050 and 1051, is a projecting ridge, annotated as 1042.

Two openings are present on the body 970, labeled as 1061 and 1060. Specifically, opening 1061 is located on the middle rightmost portion and serves the functional purpose of housing the attachment actuator 210. Directly below this, another opening, labeled as 1060, is engineered to accommodate the lock engagement actuator 212.

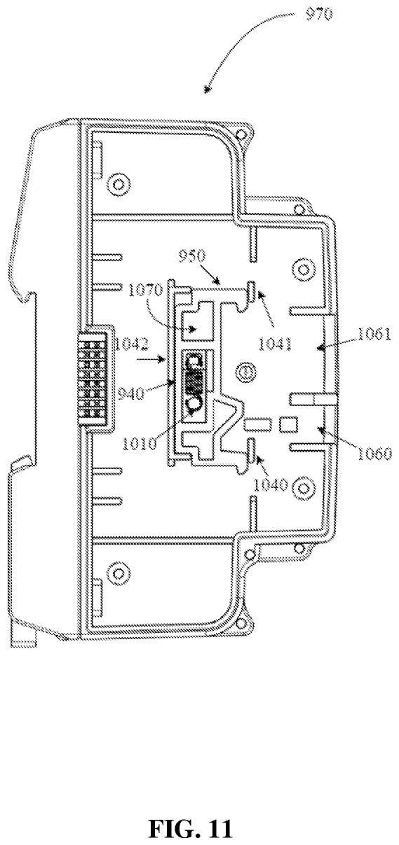

Please refer to FIG. 10 and FIG. 11. Above the opening 1061 are two engagement projections: the first one is designated by reference numeral 1041, and the second one by 1040. Collectively, these engagement projections, 1040 and 1041, together with the projecting ridge 1042, delineate a space, annotated as 1070, within which the longitudinal displacement element 950 is designed to operate. This longitudinal displacement element 950 moves longitudinally in the direction indicated by the double arrow 1030 in FIG. 10, facilitated by the action of spring 940.

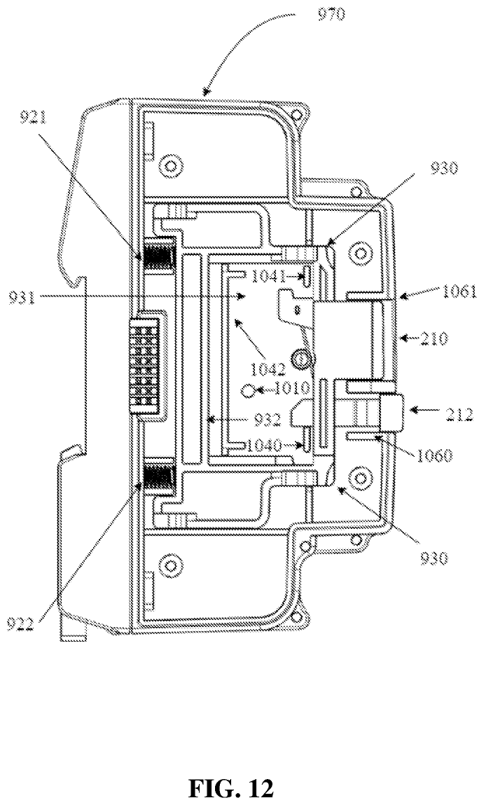

Please refer to FIG. 10 and FIG. 12. The hollow section of the transverse displacement element 930, identified as 931, is generally configured to envelop this space 1070. The transversal movement of part 930 is guided by the action of springs 921 and 922, moving in the direction indicated by arrow 1020. Upon actuation by springs 921 and 922, when the engagement projection 932 comes into contact with the projecting ridge 1042, the latter acts as a mechanical stop, thereby restricting further movement of the engagement projection 932.

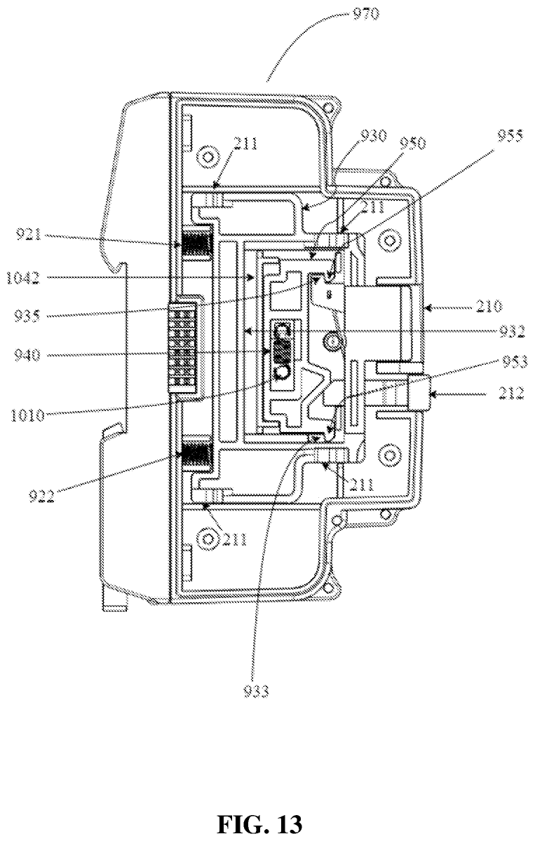

FIG. 13 illustrates the interconnection between various components in an extension module when mechanical locking elements 211 are set in a pre-engagement configuration. In FIG. 13, springs 921 and 922 are compressed, providing a force that propels the transverse displacement element 930 to the right. The engagement component 955, located on the longitudinal displacement element 950, is designed to interact with the engagement component 935 on the transverse displacement element 930. This interaction restricts further rightward movement of the transverse displacement element 930. Similarly, the engagement component 953 on the longitudinal displacement element 950 is designed to engage with the engagement component 933 on the transverse displacement element 930, also preventing further rightward movement. Spring 940 remains in its normal state during this configuration.

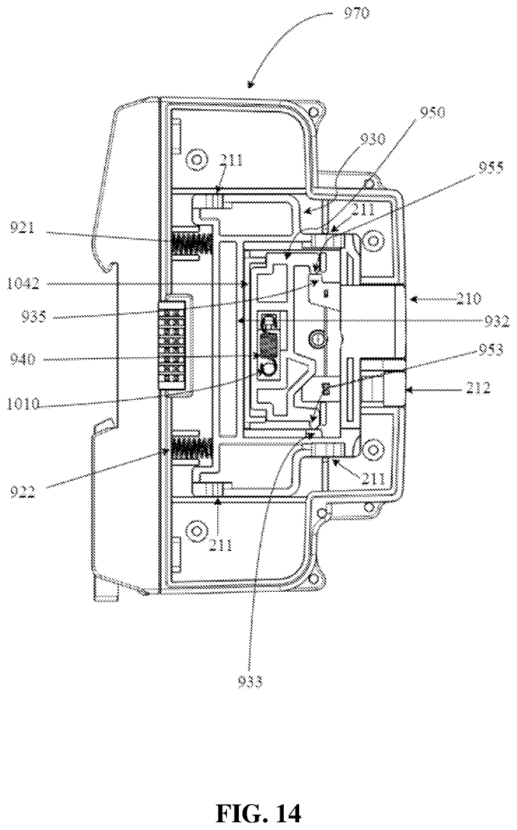

FIG. 14 illustrates the connection among various components within an extension module when the mechanical locking elements, denoted by reference numeral 211, are positioned in a locked state. When module 130 is connected to module 120, as represented in FIG. 6, a user can activate the lock engagement actuator, referenced by numeral 212. This activation causes the longitudinal displacement element, marked as 950, to shift upward. During this upward motion, engagement components identified as 935 and 933 detach from their associated counterparts, 955 and 953, respectively. This detachment permits the transverse displacement element, labeled as 930, to advance further in the rightward direction. The progression in this direction persists until the projecting ridge, having reference numeral 1042, blocks the forward motion of the engagement projection, 932. Simultaneously, the spring, designated by 940, expands, applying a force tending to move the longitudinal displacement element 950 in the downward direction. However, this potential downward movement is halted as engagement components 933 and 935 reestablish connection with their counterparts 953 and 955. In this position, both the longitudinal displacement element 950 and the transverse displacement element 930 collaborate to achieve and sustain a stabilized state.

In the depiction of FIG. 14, to detach module 130 from module 120, a user needs only to actuate the attachment actuator, referenced as 210. Upon such actuation, the longitudinal displacement element 950 is driven in the downward direction by the force exerted from spring 940. Subsequently, engagement components 935 come into engagement with engagement components 955, while engagement components 933 engage with engagement components 953, as illustrated in FIG. 13. Concurrently, the mechanical locking elements 211 return to their pre-engagement configuration.

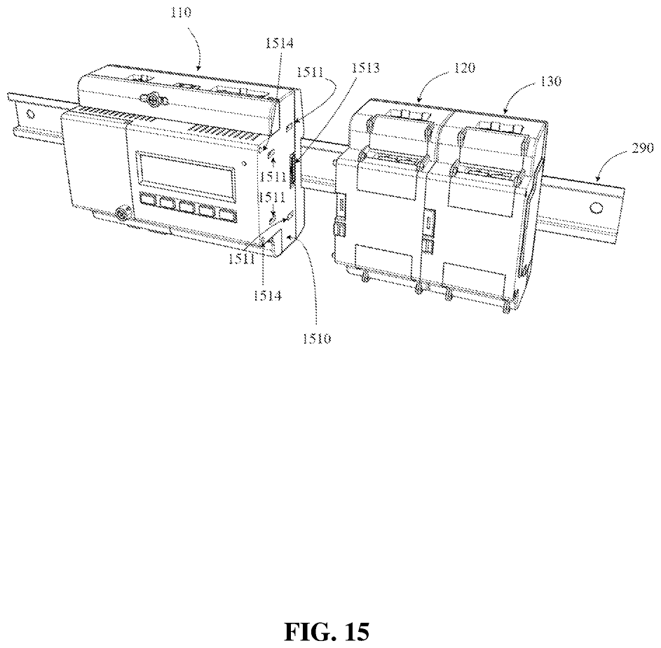

FIG. 15 illustrates a power meter assembly, which includes power meter 110, power meter extension module 120, and power meter extension module 130. The right lateral aspect of power meter 110, as denoted by reference numeral 1510, is analogous to the right lateral aspect of module 120, which is identified by reference numeral 260. Access holes, represented by numeral 1514, are located on the right lateral aspect of power meter 110, specifically on the area indicated by reference numeral 1510. Additionally, engagement apertures, represented by numeral 1511, are present on the right lateral aspect of power meter 110. An electrical interconnection is established between modules 120 and power meter 110 through the engagement of a male connector, identified as element 1513, with its complementary female connector, designated by reference numeral 233. The mechanism for securing module 120 to power meter 110 mirrors that used for joining module 130 to module 120. For an in-depth exposition, refer to the earlier relevant discussions. Further elaboration is omitted herein.

Embodiments of the teachings of the present disclosure have been described in an illustrative manner. It is to be understood that the terminology that has been used, is intended to be in the nature of words of description rather than of limitation. Many modifications and variations of the embodiments are possible in light of the above teachings. Therefore, within the scope of the appended claims, the embodiments can be practiced other than specifically described.

What is claimed is:

1. A power meter assembly comprising:
a power meter housed within a first housing, designed to measure electrical parameters at any metered location within a power distribution system, and including at least one engagement aperture and at least one access hole strategically positioned on a lateral aspect of the first housing to accommodate complementary assembly components;
a power meter extension module enclosed in a second housing, intended to augment the functionality of the power meter, which comprises:
at least one cylindrical protrusion positioned on its lateral aspect,
specifically designed to align with and be inserted into the access hole of the power meter, facilitating precise alignment and positioning during assembly;
at least one mechanical locking element located on the lateral aspect; and
a dynamic locking mechanism situated on the lateral aspect of the second housing, including a transverse displacement element equipped with an actuator, a longitudinal displacement element equipped with an actuator; and
at least one mechanical locking element forming part of the dynamic locking mechanism and located on the lateral aspect;
wherein actuation of the attachment actuator on the transverse displacement element primes the mechanical locking element into a pre-engagement configuration, facilitated by the coordinated interaction between the transverse and longitudinal displacement elements, allowing for the mechanical locking element's seamless insertion into the engagement aperture;
wherein upon activation of the lock engagement actuator, the mechanical locking element transitions into a locked state, a result of the collaborative action of the transverse and longitudinal displacement elements, ensuring a robust and secure connection between the power meter and the extension module through the interlocking of the cylindrical protrusion within the access hole.

2. The power meter assembly of claim 1, wherein the power meter further includes a male connector, positioned on the lateral aspect of the first housing, and the power meter extension module further comprises a corresponding female connector, situated on the lateral aspect of the second housing; the male connector and female connector being configured to engage with each other, thereby effectuating an electrical interconnection between the power meter and the power meter extension module when the two modules are interconnected.

3. The power meter assembly of claim 1, wherein during actuation of the attachment actuator, the engagement component on the longitudinal displacement element is structured to interact with the engagement component on the transverse displacement element, such interaction restricting further lateral movement of the transverse displacement element, and wherein spring elements associated with the displacement elements are compressed to provide a force directing the transverse displacement element, maintaining the mechanical locking elements in a pre-engagement configuration.

4. The power meter assembly of claim 1, wherein upon activation of the lock engagement actuator, the longitudinal displacement element shifts in an upward direction, causing engagement components of the transverse and longitudinal displacement elements to detach from their corresponding counterparts, allowing the transverse displacement element to progress laterally until its motion is obstructed by a projecting ridge, and wherein in this position, both the longitudinal displacement element and the transverse displacement element cooperate to secure and maintain a locked state.

5. The power meter assembly of claim 4, wherein the coupling of module 120 to the power meter enables user activation of the lock engagement actuator, inducing an upward displacement of the longitudinal displacement element due to force applied to the slope-shaped engagement component associated with the longitudinal displacement element.

6. A power meter extension module enclosing in a housing, comprising:
at least one engagement aperture and at least one access hole strategically located on a first lateral aspect of the housing to engage with complementary assembly components;
at least one cylindrical protrusion situated on a second, opposite lateral aspect, purposefully configured to align with and insert into an access hole of either a power meter or an additional power meter extension module, ensuring accurate alignment and stable assembly;
at least one mechanical locking element positioned on the second lateral aspect; and
a dynamic locking mechanism also positioned on the second lateral aspect of the housing, which incorporates a transverse displacement element and a longitudinal displacement element, with each element furnished with its own actuator.

7. A method for coupling a first power meter extension module, affixed on a DIN rail, to a second power meter extension module through an angled rotational mechanism, the method entailing:
initiating an attachment actuator located on the second module;
positioning the second module at an acute inclination relative to the first module whilst retaining the initiated attachment actuator;
coordinating cylindrical protrusions on the second module with their corresponding access holes present on the first module;
executing a rotation of the second module in a designated arc towards the first module;
upon the two modules aligning in a co-planar manner, engaging specific mechanical locking elements into matching apertures on the first module;
triggering a lock engagement actuator, thereby ensuring a firm connection between the two modules.
